(19) United States
(12) Patent Application Publication
(10) Pub. No.: US 2025/0022938 A1
(43) Pub. Date: Jan. 16, 2025

(54) GATE HARD MASK DESIGN FOR IMPROVED SOURCE/DRAIN FORMATION

(71) Applicant: Taiwan Semiconductor Manufacturing Company, Ltd., Hsin-Chu (TW)

(72) Inventors: Yao-Hsuan Lai, Taoyuan City (TW); Hung-Ju Chou, Hsinchu (TW); Chih-Chung Chang, Nantou County (TW); Wei-Yang Lee, Taipei City (TW); Yu-Shan Lu, Zhubei City (TW); Yu-Ling Hsieh, Pingtung City (TW)

(21) Appl. No.: 18/352,071

(22) Filed: Jul. 13, 2023

(51) Int. Cl. H01L 29/66; H01L 21/8234; H01L 27/088; H01L 29/08

(52) U.S. Cl. CPC H01L 29/66545; H01L 21/823418; H01L 21/823468; H01L 21/823481; H01L 27/088; H01L 29/0847

(57) ABSTRACT

One aspect of the present disclosure pertains to a method of forming a semiconductor structure. The method includes forming an active region over a substrate, forming a dummy gate layer over the active region, forming a hard mask layer over the dummy gate layer, forming a patterned photoresist over the hard mask layer, and performing an etching process to the hard mask layer and the dummy gate layer using the patterned photoresist, thereby forming patterned hard mask structures and patterned dummy gate structures. The patterned hard mask structures are formed with an uneven profile having a protruding portion. The protruding portion of each of the patterned hard mask structures has a first width, wherein each of the patterned dummy gate structures has a second width, and the first width is greater than the second width.

### BACKGROUND

The integrated circuit (IC) industry has experienced exponential growth. Technological advances in semiconductor manufacturing have produced generations of ICs, where each generation has smaller and more complex circuits than the previous generation. In the course of IC evolution, functional density (i.e., the number of interconnected IC devices per chip area) has generally increased while geometry size (i.e., dimensions and/or sizes of IC features and/or spacings between these IC features) has decreased. Typically, scaling down has been limited only by an ability to lithographically define IC features at the ever-decreasing geometry sizes.

As feature sizes continue to decrease, the spacing between adjacent source/drain features become tighter, causing epitaxial merge between source/drain features of different active regions. In some instances, the epitaxial merge is undesirable, such as when p-type epitaxial features for different transistor devices are shorted together. The merge issues adversely affect yield and wafer acceptance testing (WAT) performance. One reason for epitaxial merge is due to over-etch when forming source/drain trenches, which may cause isolation structures between active regions to break off or become unstable. Source/drain features may grow horizontally through the broken portions of the isolation structures, thereby merging with adjacent source/drain features.

Therefore, although existing methods of forming source/drain features have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a flow chart of a method to form a semiconductor structure having source/drain features without epitaxial merge, according to an embodiment of the present disclosure.

FIG. 1B illustrates a flow chart of a method to pattern a hard mask and dummy gate layer, which prepares for forming a semiconductor structure having source/drain features without epitaxial merge, according to an embodiment of the present disclosure.

FIGS. 2-7 illustrate the formation of a semiconductor structure at intermediate stages of fabrication and at cross-sectional views cut along the length of an active region, processed in accordance with the method of FIG. 1A, according to an embodiment of the present disclosure.

FIGS. 8-10 illustrate a semiconductor structure at intermediate stages of fabrication and cut along a cross-sectional view across multiple source/drain regions of an active region, according to an embodiment of the present disclosure.

FIG. 11 illustrate a semiconductor structure at an intermediate stage of fabrication to prepare for forming a semiconductor structure having source/drain features that merge and source/drain features that do not merge, according to another embodiment of the present disclosure.

FIG. 12 illustrate a semiconductor structure having source/drain features that merge and source/drain features that do not merge, cut along multiple source/drain features, according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm.

The present disclosure relates to semiconductor structures having source/drain features that do not merge with other source/drain features. One reason for epitaxial merging is due to over-etch when forming source/drain trenches, which may cause isolation structures between active regions to break off or become unstable. Source/drain features may grow horizontally through the broken portions of the isolation structures, thereby merging with adjacent source/drain features. One reason for the over-etch issue is due to the dummy gate and hard mask dimensions being too small, allowing for excessive global etching gas to eat at the source/drain regions and the isolation structures when forming the source/drain trenches. The present disclosure contemplates enlarging the hard mask profile to block excess global etching gas. Due to the gate hard mask profile design, the source/drain trenches are formed to be shallower and not causing breakage of isolation structures, thereby preventing undesired source/drain epitaxial merge.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

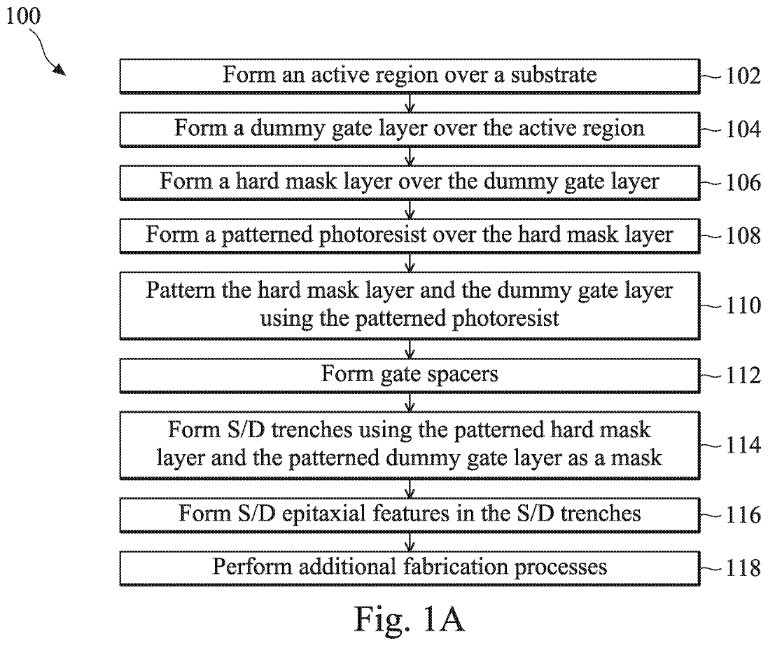

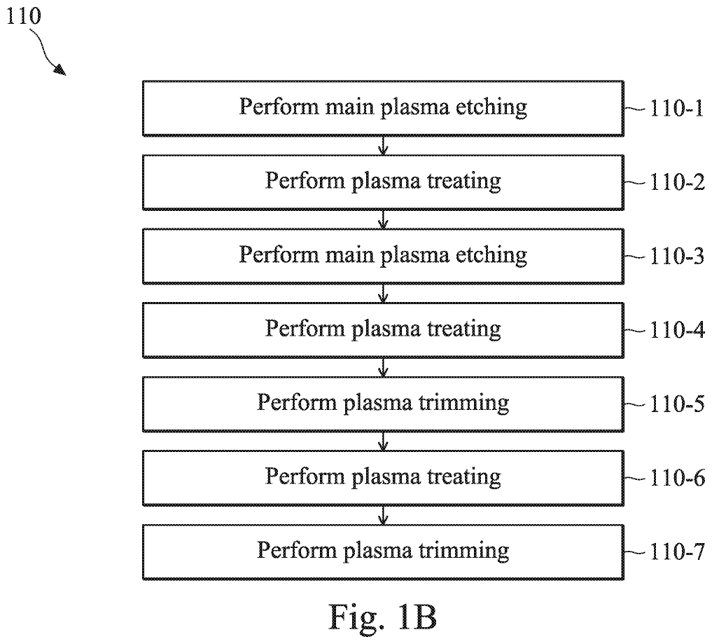

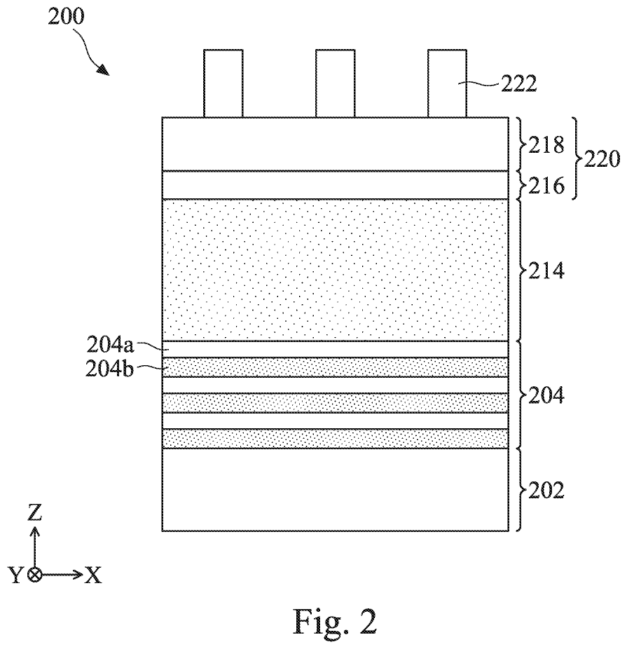

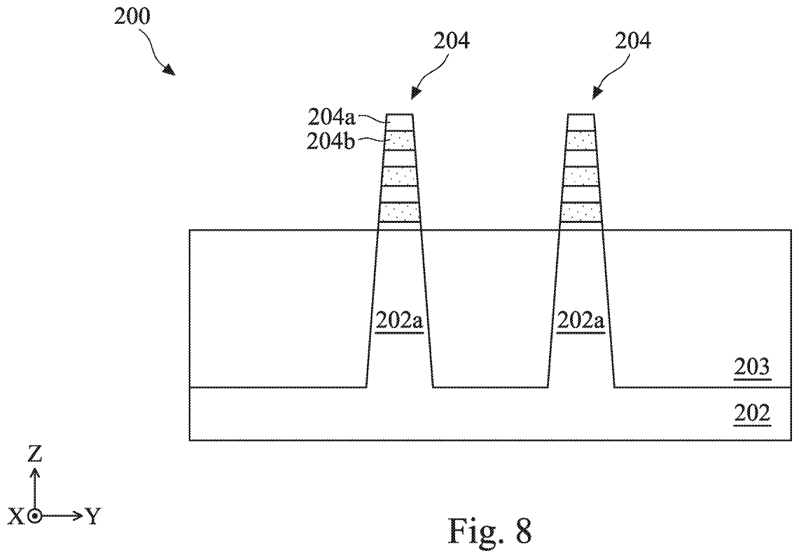

FIG. 1A illustrates a flow chart of a method 100 to form a semiconductor structure 200 having source/drain features without epitaxial merge. Method 100 is described with reference to FIGS. 2-7, which depict the formation of the semiconductor structure 200 at intermediate stages of fabrication and at a cross-sectional view cut along the length of an active region 204 over (or as part of) a substrate 202. Method 100 is also described with reference to FIGS. 8-10, which depicts the formation of the semiconductor structure 200 at intermediate stages of fabrication and at a cross-sectional view cut along source/drain regions of the active regions 204. Referring back to FIG. 1A, the method 100 at operation 110 is further broken down and described in FIG. 1B, which illustrates a flow chart of operation 110 to pattern a hard mask and dummy gate layer using a multi-etch process according to an embodiment of the present disclosure.

Referring now to FIG. 2, the method 100 at operation 102 forms an active region 204 over a substrate 202. The substrate 202 may be a silicon (Si) substrate, or a substrate having other semiconductor materials such as germanium (Ge), silicon carbide (SiC), silicon germanium (SiGe), or diamond. The active region 204 may be a fin active region protruding above the substrate 202. For a GAA FET structure (like as shown), the active region 204 includes a stack of interleaved first and second semiconductor layers 204a and 204b. The first semiconductor layers 204a have a different material composition than the second semiconductor layers 204b. For example, each of the first semiconductor layers 204a is made of silicon and each of the second semiconductor layers 204b is made of silicon germanium. The first semiconductor layers 204a may be of a same material composition as the substrate 202. For a Fin FET structure (not shown), the active region 204 includes a single fin semiconductor layer 204a or 204b over the substrate 202.

The active region 204 extends lengthwise along the x direction. And in the y direction, there may be adjacent active regions 204 similarly formed (see FIG. 8), also extending lengthwise along the x direction. FIG. 8 shows a view of the semiconductor structure 200 at operation 102, but at a cross-sectional view cut along the y direction across multiple active regions 204. Specifically, the cross-sectional view is cut along source/drain regions of the multiple active regions 204. As shown in FIG. 8, the active regions 204 are separated from each other in the y direction by an isolation structure 203 over the substrate 202. The substrate 202 may include protruding portions 202a that penetrate through the isolation structure 203, and the active regions 204 may extend from top surfaces of the protruding portions 202a. Each of the protruding portions 202a are interposed by the isolation structure 203. As such, the isolation structure 203 interfaces with a top surface of the substrate 202 and side surfaces of the protruding portions 202a. The isolation structure 203, which may be a shallow trench isolation (STI) layer, provides isolation between adjacent active regions 204, which may include semiconductor stacks having the first and second semiconductor layers 204a and 204b. In an example process, a dielectric material for the isolation structure 203 is deposited over the workpiece using CVD, subatmospheric CVD (SACVD), flowable CVD, physical vapor deposition (PVD), spin-on coating, and/or other suitable process. Then the deposited dielectric material is planarized and recessed until the active regions 204 rises above the isolation structure 203. The dielectric material for the isolation structure 203 may include silicon oxide, silicon oxynitride, fluorine-doped silicate glass (FSG), a low-k dielectric, combinations thereof, and/or other suitable materials.

Referring back to FIG. 2, the method 100 at operation 104 forms a dummy gate layer 214 over the active region 204. The dummy gate layer 214 may be formed through any suitable deposition process. The dummy gate layer 214 may include polysilicon, amorphous silicon, or microcrystal silicon. Still referring to FIG. 2, the method 100 at operation 106 forms a hard mask layer 220 over the dummy gate layer 214. The hard mask layer 220 may include multiple dielectric layers (also referred to as dielectric films). The hard mask layer 220 may be formed by thermal growth, atomic layer deposition (ALD), chemical vapor deposition (CVD), high density plasma CVD (HDP-CVD), other suitable deposition processes. In the embodiment shown, the hard mask layer 220 includes a silicon oxide layer 218 formed over a silicon nitride layer 216. For example, the silicon nitride layer 216 is deposited over the dummy gate layer 214, then the silicon oxide layer 218 is deposited over the silicon nitride layer 216. In another embodiment, the silicon nitride layer 216 may be formed over the silicon oxide layer 218. In other embodiments, additional silicon oxide and/or silicon nitride layers may be formed as part of the hard mask layer 220. In an embodiment, the dummy gate layer 214 has a greater thickness than the hard mask layer 220, and the silicon oxide layer 218 has a greater thickness than the silicon nitride layer 216.

Still referring to FIG. 2, the method 100 at operation 108 forms a patterned photoresist 222 over the hard mask layer 220. The patterned photoresist 222 may be formed by first depositing a photoresist layer on the hard mask layer 220, then patterning the photoresist layer through an exposure and developing process, also referred to as lithographic patterning. For example, forming the patterned photoresist may include spin-on coating a photoresist layer, soft baking the photoresist layer, mask aligning, exposing, post-exposure baking, developing the resist layer, rinsing, and drying (e.g., hard baking). Alternatively, the lithographic patterning process may be implemented, supplemented, or replaced by other methods such as mask-less photolithography, electron-beam writing, and ion-beam writing. In any case, the patterned photoresist 222 is formed and used as masks to pattern the hard mask layer 220 and the dummy gate layer 214.

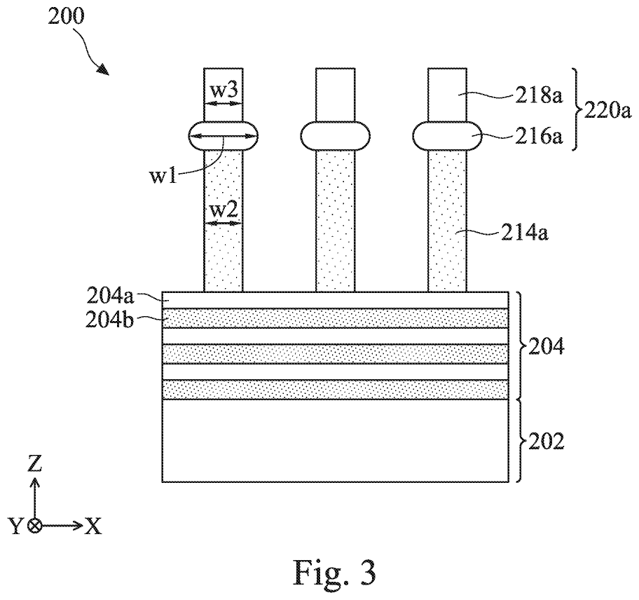

Now referring to FIG. 3, using the patterned photoresist 222 as a mask, the method 100 at operation 110 performs an etching process (also referred to as a patterning process) to pattern the hard mask layer 220 and the dummy gate layer 214. The etching process in operation 110 is designed to pattern the dummy gate layer 214 and the hard mask layer 220 to have an uneven sidewall profile having a protruding portion in order to control a subsequent source/drain etching process applied to the source/drain regions by the etch loading effect such that the corresponding source/drain etch rate is reduced. The etching process may include wet etching, dry etching, or a combination thereof. The etching process forms a patterned hard mask layer and a patterned dummy gate layer, also referred to as patterned stacks having patterned dummy gate structures 214a and patterned hard mask structures 220a. The patterned hard mask structures 220a include patterned silicon nitride layers 216a and patterned silicon oxide layers 218a. As shown, the patterned hard mask structures 220a are etched and patterned to have an uneven profile having a protruding portion. In an embodiment, the protruding portion is the patterned silicon nitride layer 216a. The protruding portion of each of the patterned hard mask structures 220a has a width w1 along the x direction, and the width w1 is greater than a width w2 of the patterned dummy gate structures 214a. For example, each of the patterned silicon nitride layers 216a has a width w1 greater than a width w2 of the patterned dummy gate structures 214a. In an embodiment, the ratio of w1/w2 is greater than 1.1. Although not explicitly shown, the patterned silicon oxide layers 218a may also have a greater width than that of the patterned dummy gate structures 214a (i.e., w3 is greater than w2). As will be described with respect to operation 114, it is advantageous to have wider hard mask structure profiles (patterned silicon nitride and/or silicon oxide layers 216a and 218a) for controlling source/drain trench formation. In an embodiment, the width w1 of the patterned silicon nitride layer 216a is greater than the width w3 of the patterned silicon oxide layer 218a, and the width w3 of the patterned silicon oxide layer 218a is greater than the width w2 of the patterned dummy gate structure 214a. Still referring to FIG. 3, as part of operation 110, the patterned photoresist 222 is removed.

The etching process of operation 110 is described in more detail with reference to FIG. 1B. As shown in FIG. 1B, the etching process is a multi-step etching process that includes one or more main plasma etching steps (e.g., steps 110-1 and 110-3), one or more plasma treating steps (e.g., 110-2, 110-4, and 110-6), and one or more plasma trimming steps (e.g., steps 110-5 and 110-7). Each of the main plasma etching steps include applying halogen-containing gases such as Cl2, Br2, HBr, HCl, or combinations thereof. Each of the plasma trimming steps also include applying halogen-containing gases such as Cl2, Br2, HBr, HCl, or combinations thereof. However, as will be described below, the main plasma etching steps and the plasma trimming steps differ in timing and the duration of applying bias voltage and the halogen-containing gases. Each of the plasma treating steps may include O2 ashing, CO2 ashing, nitrogen plasma treatment, or combinations thereof.

FIG. 1B is describe starting with step 110-1. At step 110-1, the operation 110 performs a first main plasma etching to do initial patterning of the hard mask layer 220 and the dummy gate layer 214. After step 110-1, general stacks of patterned structures may be formed through an initial pattern transfer, but with the patterned photoresist 222 still remaining over the stacks of patterned structures. In an embodiment, the first main plasma etching step 110-1 applies a bias voltage and a Cl2 or HBr gas. Then, at step 110-2, the operation 110 performs a first plasma treating to fully (or partially) remove the patterned photoresist 222. The first plasma treating step 110-2 may include O2 ashing, CO2 ashing, nitrogen plasma treatment, or combinations thereof. In an embodiment, the first plasma treating step 110-2 includes O2 ashing. Then, a second main plasma etching step 110-3 and a second plasma treating step 110-4 may be performed. The second main plasma etching step 110-3 could be optional and may be similar to the first main plasma etching step, and the second plasma treating step 110-4 could be optional and may be similar to the first plasma treating step 110-2 etching step. In an embodiment, the second main plasma etching step 110-3 applies a bias voltage and a Cl2 or HBr gas to do further patterning. The bias voltage applied in step 110-3 may be similar to or different from the bias voltage applied in step 110-1. In an embodiment, the second plasma treating step 110-4 includes CO2 ashing to remove residue chemicals in the earlier steps, or to further remove remaining portions of the patterned photoresist 222. Then, at step 110-5, the operation 110 performs a first plasma trimming step to trim the stacks of patterned structures. This may also be referred to as a first soft-landing step. In an embodiment, the first plasma trimming step 110-5 trims the patterned structures to form the protruding portions of the patterned hard mask structures 220a (see FIG. 3). For example, the plasma trimming step 110-5 trims the silicon nitride layer 216 at a slower rate than the dummy gate layer 214 and/or the silicon oxide layer 218, thereby forming an uneven profile having the protruding portion. In an embodiment, the first plasma trimming step 110-5 applies a bias voltage and a Cl2 or HBr gas. Then, a third plasma treating step 110-6 may be performed. The third main plasma treating step 110-6 could be optional and may be similar to or different from the first or second plasma treating steps 110-2 and 110-4. In an embodiment, the third plasma treating step 110-4 includes nitrogen treatment to remove residue chemicals in the earlier steps, or to further remove or clean out remaining portions of the patterned photoresist 222. Then, a second plasma trimming step 110-7 may be performed. This may also be referred to as a second soft-landing step. The second plasma trimming step 110-7 could be optional and may be similar to the first plasma trimming step 110-5. In cases where the second plasma trimming step 110-7 is performed, it is performed after a plasma treating step (e.g., step 110-6). The second plasma trimming step may further trim and shape the stacks of patterned structures to form the protruding portions of the patterned hard mask structures 220a (see FIG. 3).

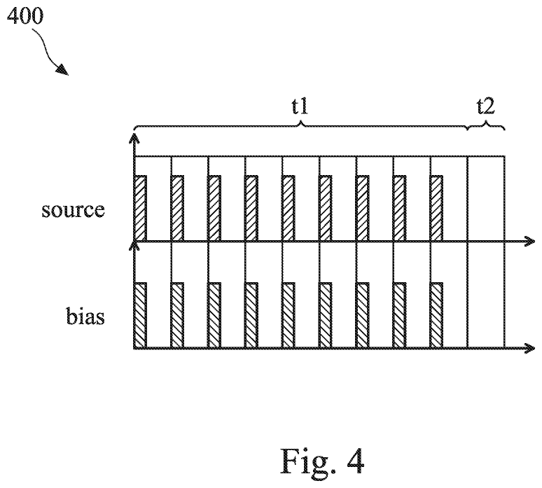

Referring now to FIG. 4, each of the plasma trimming steps 110-5 and 110-7 may be a cyclic etch process. The cyclic etch process may include multiple etch cycles 400, which repeat iteratively according to design considerations. As shown, each etch cycle 400 of the cyclic etch process includes multiple pulses of a bias voltage and multiple pulses of a gas source (i.e., halogen-containing gas flow). Each etch cycle 400 has a first time duration t1 and a second time duration t2 following the first time duration t1. The first time duration t1 is active, and the second time duration t2 is inactive. In other words, during the first time duration, the cyclic etch process includes applying multiple pulses of the bias voltage and the gas source, and during the second time duration, the cyclic etch process does not apply any bias voltage or the gas source. As such, during the first time duration t1, each etch cycle 400 includes multiple pulses of the bias voltage and gas source, and during the second time duration, each etch cycle 400 is free of the bias voltage and gas source. To achieve the uneven profile having the protruding portion in the hard mask structure 220a, the first duration t1 should be 85-95% of the total duration of the cyclic etch process and the second duration t2 should be 5-15% of the total duration of the cyclic etch process. In an embodiment, each time duration t1 in an etch cycle 400 is equal to or less than 90% the total time duration in the etch cycle 400. In other words, a ratio of t1/(t1+t2) is equal to or less than 90%.

Still referring to FIG. 4, each pulse of the multiple pulses of bias voltage and gas source are spaced apart by an off period. The multiple pulses of the bias voltage and the gas source are evenly distributed in the first time duration t1. Further, the bias voltage pulses and the gas source pulses may be applied at the same time during the time duration t1. As such, the multiple pulses of the bias voltage and gas flow are synchronized (or aligned) in time to enhance the etch effect. In some embodiments, the amplitudes of the multiple pulses of the bias voltage are same in one cyclic process, and the amplitudes of the multiple pulses of the gas source are same in the cyclic process.

Similar to the plasma trimming steps as described with respect to FIG. 4, each of the main plasma etching steps 110-1 and 110-3 may also be a cyclic etch process. In the same way, the cyclic etch process for the main plasma etching steps may include applying multiple pulses of bias voltage and gas source for multiple etch cycles. The gas source for the main plasma etching steps may be similar to the gas source for the plasma trimming steps (e.g., both using Cl2 or HBr gas). However, the bias voltage applied for the main plasma etching steps may be different than the bias voltage applied for the plasma trimming step. For example, a higher voltage is applied for main etching than for trimming. Further, each etch cycle for the main plasma etching steps may have a first time duration t3 where the pulses are active and a second time duration t4 where the pulses are off. However, unlike the plasma trimming steps, the main plasma etching steps will have a much smaller time duration t4 (as compared to t2) where the cyclic etch process does not apply any bias voltage or gas source. In an embodiment, there is no time duration t4 at all and there is only the time duration t3 where periodic pulses of bias voltage and gas source are applied. In another embodiment, if there is any time duration t3, the time duration t3 is greater than 99% the total time duration in the etch cycle. In other words, a ratio of t3/(t3+t4) is greater than 99%. In an embodiment, the total time duration for each main plasma etching step etch cycle is substantially greater than the total time duration for each plasma trimming step etch cycle (i.e., t3+t4 is substantially greater than t1+t2, such as 2 or more times greater). Note that the main plasma etching steps are coarse etching steps to form general patterned structures, and the plasma trimming steps are fine etching steps to form desired profiles and surfaces. As already described, the main plasma etching steps and the plasma trimming steps may have different etching time profiles to achieve this. Further, the plasma trimming steps may include other more targeted parameters compared to the main plasma etching steps.

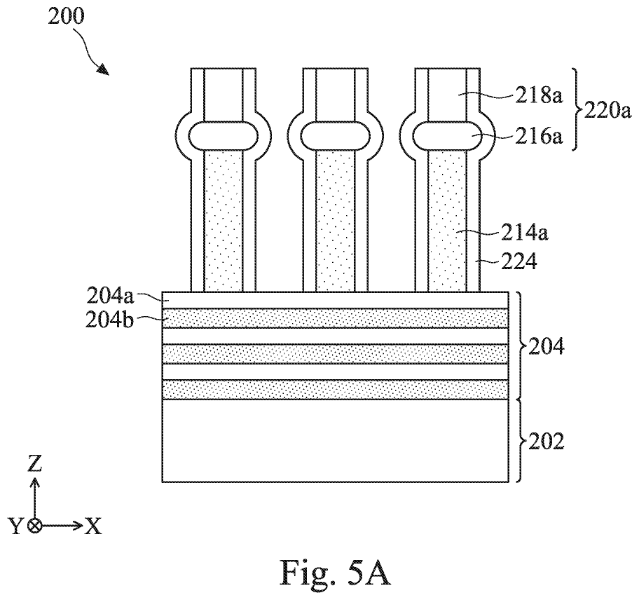

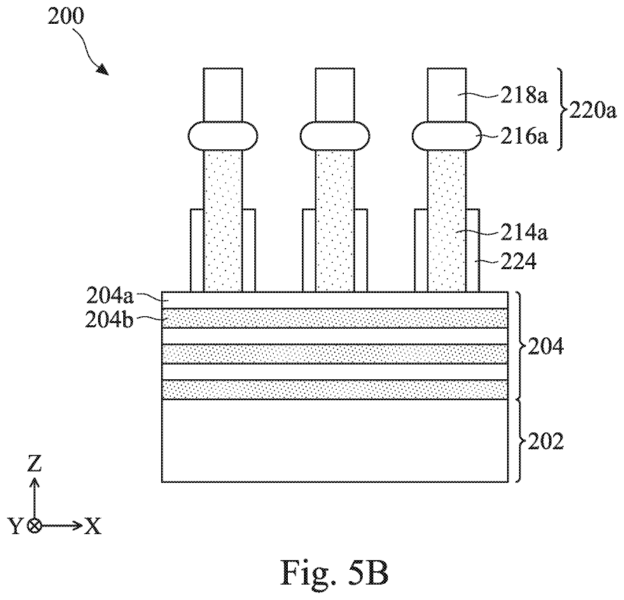

Referring now to FIG. 5A, after operation 110 and its multi-step etching processes 110-1 to 110-7, the method 100 at operation 112 forms gate spacers 224 over sidewalls of the patterned stack structures (i.e., patterned hard mask structures 220a and patterned dummy gate structures 214a). The gate spacers 224 may be formed by a spacer deposition process and a spacer etching process. For example, a spacer deposition process is performed to form a conformal spacer layer over the patterned stack structures and over top surfaces of the active region 204. The spacer deposition process may include processes such as CVD, PVD, ALD, HDPCVD, MOCVD, RPCVD, PECVD, LPCVD, ALCVD, APCVD, plating, other suitable methods, or combinations thereof. A spacer etching process is then performed that selectively etches the horizontal portions (x direction) of the spacer layer to form gate spacers 224 only or substantially only on sidewalls of the patterned stack structures. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

Referring now to FIG. 5B, and still referring to operation 112, the gate spacers 224 may be further processed such that top portions of the gate spacers 224 are removed. This removal process may include selectively etching the gate spacers 224 without substantially etching the patterned hard mask structures 220a, the patterned dummy gate structures 214a, and the active regions 204. In an embodiment, gate spacer portions that are on sidewalls of the patterned hard mask structures 220a are removed, while a remaining portion of the gate spacers 224 still lines a sidewall portion of the patterned dummy gate structures 214a. Note that in some embodiments, this additional removal process is skipped, and the structure in FIG. 5A directly continues to operation 114.

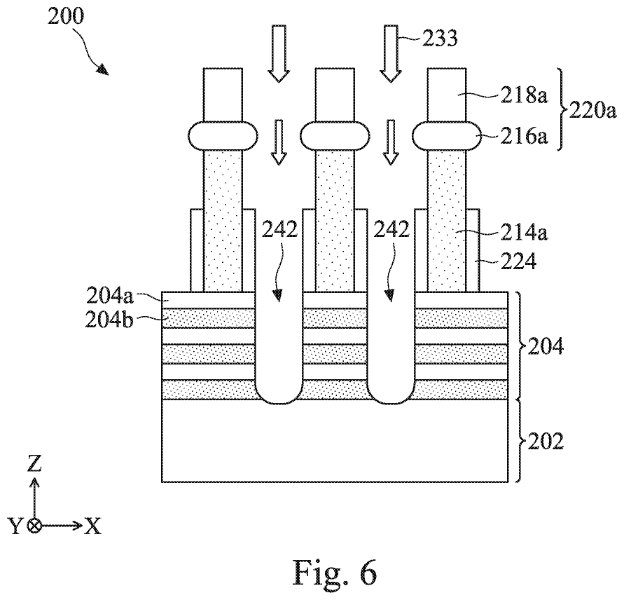

Referring now to FIG. 6, the method 100 at operation 114 forms source/drain (S/D) trenches 242 using the patterned hard mask layer (i.e., patterned hard mask structures 220a), the patterned dummy gate layer (i.e., patterned dummy gate structures 214a), and the gate spacers 224 as an etch mask. The S/D trenches 242 are formed by applying a global etching gas 233 downwards and between adjacent hard mask structures 220a. The global etching gas 233 is applied to S/D regions of the active regions 204. As such, the S/D regions are recessed to form the S/D trenches 242. The amount of the global etching gas that reaches the S/D regions is impacted by the uneven profile of the patterned stack structures. Specifically, due to the protruding portion of the patterned hard mask structures 220a (e.g., patterned silicon nitride layer 216a), an amount of the global etching gas decreases after the global etching gas passes between adjacent protruding portions of the patterned hard mask structures. As indicated by the change in size of the white arrows, the decrease in global etching gas is attributed to the protruding portions blocking and trapping some of the etching gas traveling to the S/D regions.

Still referring to FIG. 6, the S/D trenches 242 have sidewalls defined by the remaining portions of the active regions 204. The S/D trenches 242 may be formed by a dry etching process, a wet etching process, other suitable etching process, or combinations thereof. In some embodiments, the etching process may include alternative etchants to separately and alternately remove semiconductor layers 204a and semiconductor layers 204b. In some embodiments, parameters of the etching process are configured to etch S/D regions of the active regions 204 with minimal (to no) etching to the patterned stack structures (i.e., patterned dummy gate structures 214a and patterned hard mask structures 220a, and gate spacers 224).

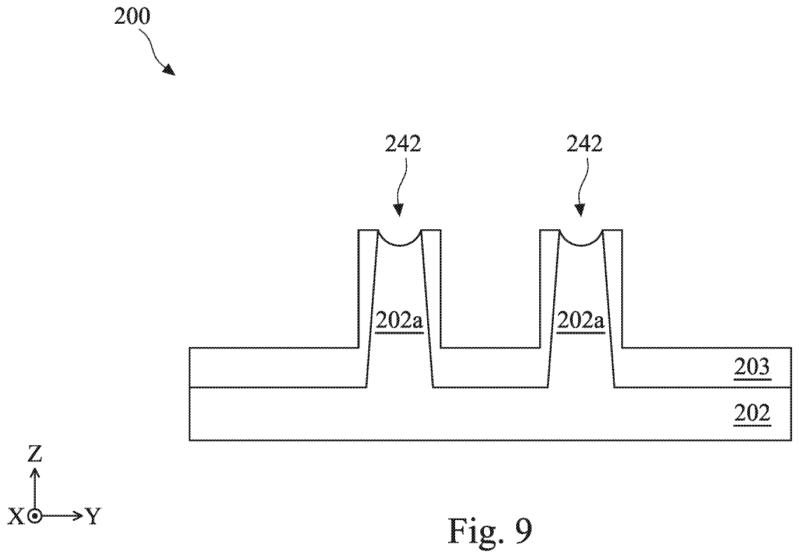

Still referring to FIG. 6, the S/D trenches 242 extend into the substrate 202 past the bottommost semiconductor layers 204b of the active region 204. However, due to the decrease in global etching gas, the extension into the substrate 202 is not deep, which is desirable for forming subsequent S/D features without epitaxial merge issues. Turning now to FIG. 9 (showing the same cross-sectional view of FIG. 8 and still referring to operation 114), note that the global etching gas will also partially etch the isolation structure 203. In the embodiment shown, the isolation structure 203 is etched deeper in the negative z direction than the top surfaces of the protruding portions 202a. Note that after forming the S/D trenches 242, the isolation structure 203 still has a portion that completely surrounds the protruding portions 202a of the substrate 202. Specifically, there remains sidewall portions of the isolation structure 203 that lines and protects the sidewalls of the protruding portions 202a. The sidewall portions of the isolation structure 203 guides and direct the direction of subsequent S/D epitaxial feature growth. If these sidewall portions are broken or unstable due to over etching, subsequent S/D epitaxial growth may result in unwanted horizontal growth that merge adjacent S/D epitaxial features.

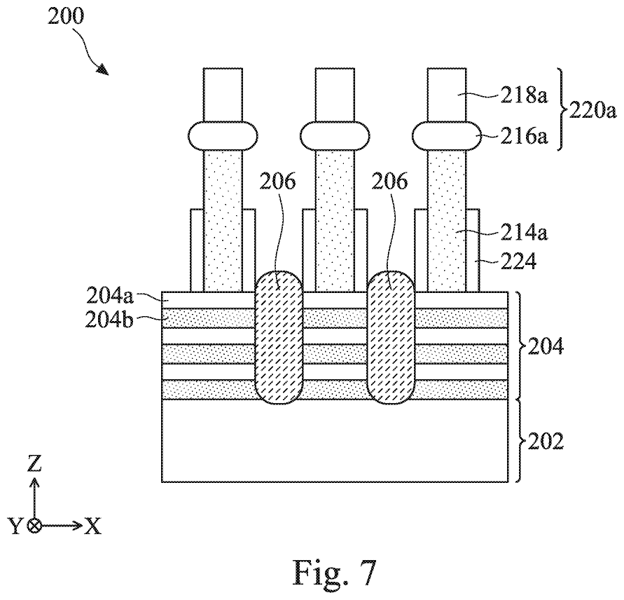

Referring now to FIG. 7, the method 100 at operation 116 forms S/D epitaxial features 206 in the S/D trenches 242. The S/D epitaxial features 206 may include n-type source/drain features that correspond with n-type transistor regions or p-type source/drain features that correspond with p-type transistor regions. The source/drain features may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 202 and/or active regions 204 (in particular, semiconductor layers 204a). The S/D epitaxial features 206 are doped with n-type dopants and/or p-type dopants. In some embodiments, for the n-type transistors, S/D epitaxial features 206 include silicon and can be doped with carbon, phosphorous, arsenic, other n-type dopant, or combinations thereof (for example, forming Si:C epitaxial source/drain features, Si:P epitaxial source/drain features, or SiC:P epitaxial source/drain features). In some embodiments, for the p-type transistors, S/D epitaxial features 206 include silicon germanium or germanium and can be doped with boron, other p-type dopant, or combinations thereof (for example, forming SiGe:B epitaxial source/drain features). In the present embodiment, the S/D epitaxial features 206 are p-type S/D features designed to not merge with adjacent p-type S/D features.

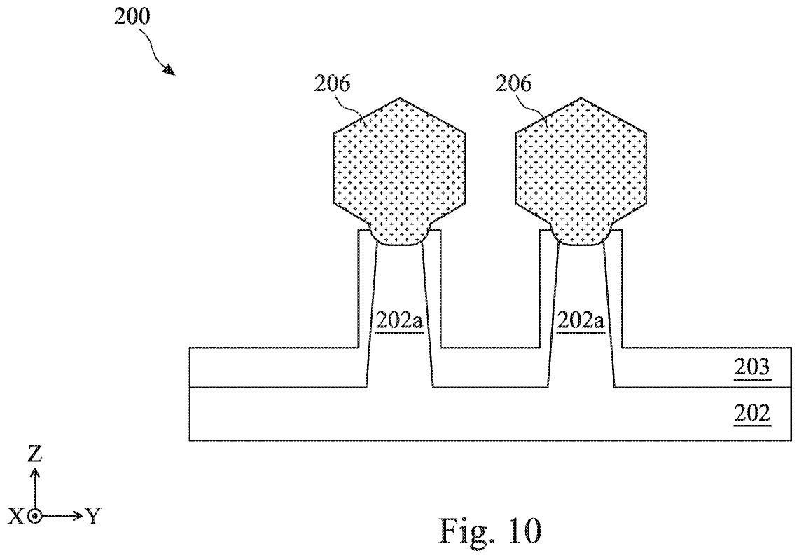

Turning now to FIG. 10 (showing the same cross-sectional view of FIG. 9 and still referring to operation 116), S/D epitaxial features 206 are formed on the etched top surfaces of the protruding portions 202a of the substrate 202. FIG. 10 shows two S/D epitaxial features 206 formed in S/D regions of two different adjacent active regions 204. Due to how sidewall portions of the isolation structure 203 are still completely intact and surrounding the protruding portions 202a, the S/D epitaxial features 206 are guided to grow substantially in the vertical direction and do not merge with respective adjacent S/D epitaxial features 206.

The method 100 at operation 118 performs additional fabrication processes to form functional semiconductor devices. For example, the method 100 removes the patterned hard mask structures 220a and performs a gate replacement process to form metal gates in place of the patterned dummy gate structures 214a. The gate replacement process may include etching away the patterned dummy gate structures 214a to form gate trenches, then filling the gate trenches with a gate metal to form gate electrodes. The gate replacement process may further include planarization processes to planarize top surfaces of the gate spacers 224 with top surfaces of the gate electrodes or a gate dielectric cap formed over the gate electrodes. For GAA devices, the method 100 may also perform a channel release process to form suspended channels before performing the gate replacement process. The method 100 may further include: forming metal contacts over the S/D epitaxial features 206 and metal contacts over the metal gates; forming interconnects having vias and metal lines over the respective metal contacts; forming redistribution structures over the interconnects; and performing IC bonding and packaging processes. Additional operations can be provided before, during, and after method 100. Further, some of the operations described herein can be moved, replaced, or eliminated for additional embodiments of method 100.

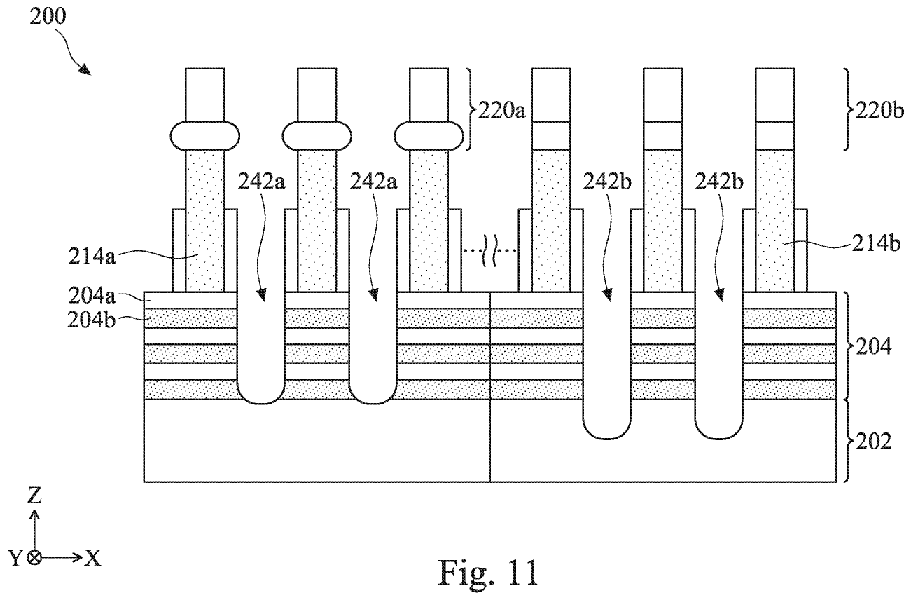

FIG. 11 illustrates another embodiment of the present disclosure incorporating the hard mask design and patterning processes described herein. Specifically, FIG. 11 shows a semiconductor structure 200 having first S/D regions with shallow S/D trenches 242a and second S/D regions with deep S/D trenches 242b. The shallow S/D trenches 242a are similar to the S/D trenches 242 previously described. The shallow S/D trenches 242a are formed due to the etching process in operation 110, resulting in an uneven hard mask profile having a protruding portion to block global etching gas when forming S/D trenches 242a. Note that the uneven profile is due to the plasma trimming steps 110-5 and/or 110-7 having unique and targeted pulsing patterns. On the other hand, the deep S/D trenches 242b are formed due to forming patterned hard mask structures 220b without the uneven hard mask profile and without the protruding portions. Therefore, there is more global etching gas penetrating through to form the deep trenches 242b. As shown, the patterned hard mask structures 220b and patterned dummy gate structures 214b have even profiles. This can be the result of adjusting the plasma trimming steps 110-5 and/or 110-7 to be more similar to the main plasma etching steps 110-1 and 110-3, for example in terms of pulse timing and duration (e.g., same t1 and t2 time durations). In another embodiment, the plasma trimming steps are omitted.

Still referring to FIG. 11, the shallow S/D trenches 242a and the deep trenches 242b may be formed in different regions of the substrate 202 (i.e., they do not have to be adjacent). For example, the shallow S/D trenches 242a are formed in S/D regions for p-type epitaxial S/D features, and the deep S/D trenches 242b are formed in S/D regions for n-type epitaxial S/D features. In some embodiments, the patterned dummy gate structures 214a and 214b and the patterned hard mask structures 220a and 220b are formed in separate processing sequences that include, for example, masking p-type S/D regions when patterning to form patterned dummy gate structures 214b and patterned hard mask structures 220b, and masking n-type transistor regions when forming patterned dummy gate structures 214a and patterned hard mask structures 220a in p-type S/D regions. Due to the different hard mask profiles for the patterned hard mask structures 220a and 220b, a single global etching step can be performed to form the S/D trenches 242a and 242b, improving the S/D engineering window.

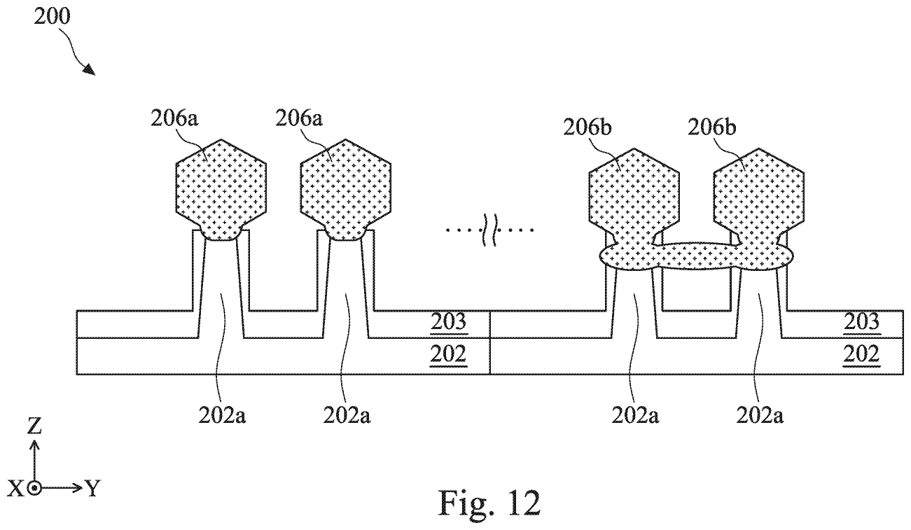

Referring now to FIG. 12, as a result of forming shallow and deep S/D trenches 242a and 242b, subsequent S/D epitaxial growth processes may form epitaxial S/D features 206b that merge and epitaxial S/D features 206a that do not merge. As described above, forming deeper S/D trenches may cause over-etching where sidewall portions of the isolation structure 203 are broken while forming shallower S/D trenches avoids this issue. In cases that have broken or weak sidewall portions in the isolation structure 203, there may be horizontal epitaxial growth that breaks through the broken sidewalls and merge with adjacent S/D features (see epitaxial S/D features 206b). The epitaxial merge may be in lower portions of the epitaxial S/D features 206b, since the lower portions of the epitaxial S/D features 206b are closer to each other than the top portions. On the other hand, referring to the epitaxial S/D features 206a, when there is no over-etching issues and sidewall portions of the isolation structure 203 remain stable, there is no merge issues because lower portions of the epitaxial S/D features 206a do not break through the sidewall portions in the isolation structure 203. In an embodiment, the epitaxial S/D features 206a are p-type S/D features designed not to merge, and the epitaxial S/D features 206b are n-type S/D features designed with freedom to merge or not merge. In some cases, it is desirable for n-type S/D features to merge to improve via contact landing and to reduce contact resistance. As shown in FIG. 12, a bottom surface of each of the epitaxial S/D features 206a is above a bottom surface of each of the epitaxial S/D features 206b. This is because the S/D trenches formed for the S/D features 206a are shallower than the S/D trenches formed for the S/D features 206b. Lower portions of the epitaxial S/D feature 206b (i.e., merged portions) break through sidewall portion in the isolation structure 203. As such, there may be sidewall portions of the isolation structure 203 vertically between lower and upper portions of the epitaxial S/D feature 206b. Note that these lower portions (merged portions) of the epitaxial S/D features 206b are not present in the epitaxial S/D features 206a.

Although not limiting, the present disclosure offers advantages for forming epitaxial S/D features. One example advantage is the ability to adjust source/drain trench depth by adjusting hard masks profiles when forming dummy gate structures. For example, the present disclosure contemplates enlarging a portion of the hard mask profile to block excess global etching gas. Due to the gate hard mask profile design, the source/drain trenches are formed to be shallower and not causing breakage of isolation structures, thereby preventing undesired source/drain epitaxial merge in an embodiment. Another example embodiment is incorporating different hard mask profile designs to form S/D features designed not to merge and S/D features with freedom to merge.

One aspect of the present disclosure pertains to a method of forming a semiconductor structure. The method includes forming an active region over a substrate, forming a dummy gate layer over the active region, forming a hard mask layer over the dummy gate layer, forming a patterned photoresist over the hard mask layer, and performing an etching process to the hard mask layer and the dummy gate layer using the patterned photoresist, thereby forming patterned hard mask structures and patterned dummy gate structures. The patterned hard mask structures are formed with an uneven profile having a protruding portion. The protruding portion of each of the patterned hard mask structures has a first width, wherein each of the patterned dummy gate structures has a second width, and the first width is greater than the second width.

In an embodiment, the dummy gate layer includes polysilicon or amorphous silicon, and the hard mask layer includes silicon oxide and silicon nitride.

In an embodiment, the hard mask layer includes a silicon oxide layer formed over a silicon nitride layer, and the protruding portion is the silicon nitride layer.

In an embodiment, the etching process is a multi-step etching process, the multi-step etching process includes one or more main plasma etching steps, one or more plasma treating steps, and one or more plasma trimming steps. The main plasma etching steps and the plasma trimming steps include applying halogen-containing gases such as Cl2, Br2, HBr, HCl, or combinations thereof. The plasma treating steps include O2 ashing, CO2 ashing, nitrogen plasma treatment, or combinations thereof. In a further embodiment, one of the plasma trimming steps is a cyclic etch process, each cycle of the cyclic etch process having multiple pulses of a bias voltage and multiple pulses of a halogen-containing gas flow. In a further embodiment, each cycle of the cyclic etch process includes a first duration t1 and a second duration t2 following the first duration, and the first duration of the cyclic etch process includes multiple pulses of the bias voltage and the second duration of the cyclic etch process is free of the bias voltage. The first duration t1 is 85-95% of a total duration of the cyclic etch process and the second duration t2 is 5-15% of the total duration of the cyclic etch process. In a further embodiment, the one of the plasma trimming step forms the protruding portion of each of the patterned hard mask structures.

In an embodiment, the method further includes forming gate spacers along sidewalls of the patterned dummy gate structures, forming source/drain (S/D) trenches between the patterned dummy gate structures and in S/D regions of the active region, and forming S/D epitaxial features in the S/D trenches. In a further embodiment, the active region is a first active region and the S/D epitaxial features are first S/D epitaxial features, and the method further includes forming a second active region over the substrate and adjacent to the first active region, forming second S/D trenches between the patterned dummy gate structures and in second S/D regions of the second active region, and forming second S/D epitaxial features in the second S/D trenches, where the first S/D epitaxial features do not merge with the second S/D epitaxial features. In a further embodiment, the forming of the S/D trenches includes etching through the S/D regions of the active region and partially etching an isolation structure that surrounds a protruding portion of the substrate, wherein after the forming of the S/D trenches, the isolation structure still has a portion that completely surround the protruding portion of the substrate.

Another aspect of the present disclosure pertains to a method of forming a semiconductor structure. The method includes depositing a dummy gate layer over an active region of a semiconductor substrate, depositing a hard mask layer over the dummy gate layer, the hard mask layer including a first dielectric film and a second dielectric film over the first dielectric film, and performing a patterning process to the hard mask layer and the dummy gate layer. The patterning process includes a first etching process having multiple etching steps and one of the etching steps is a cyclic etch process designed to form patterned stacks of the hard mask layer and the dummy gate layer with an uneven profile such that the first dielectric film of each of the patterned stacks spans a first width w1, and the dummy gate layer of each of the patterned stacks span a second width w2 less than the first width. The method further includes recessing source/drain regions of the active region by a second etching process impacted by the uneven profile of the patterned stacks.

In an embodiment, the cyclic etch process includes applying a bias voltage and a gas flow of an etch chemical, each cycle of the cyclic etch process includes a first duration t1 and a second duration t2 following the first duration. The first duration of the cyclic etch process includes multiple pulses of the bias voltage and the second duration of the cyclic etch process is free of the bias voltage. In a further embodiment, a first ratio of t1/(t1+t2) is less than 90%, and a second ratio of w1/w2 is greater than 1.1. In a further embodiment, the first duration of the cyclic etch process includes multiple pulses of the gas flow and the second duration of the cyclic etch process is free of the gas flow. In an embodiment, the multiple pulses of the bias voltage and the multiple pulses of the gas flow are synchronized. In a further embodiment, the multiple pulses of the bias voltage are evenly distributed in the first duration.

In an embodiment, the one of the etching steps is a second etch step, the cyclic etch process is a second cyclic etch process, the bias voltage is a second bias voltage, the gas flow is a second gas flow, where the first etching process further includes a first etch step, and the first etch step is a first cyclic etch process performed before the second etch step, the first cyclic etch process includes applying a first bias voltage and a first gas flow of the etch chemical, each cycle of the first cyclic etch process includes a third duration t3 and a fourth duration t4 following the third duration, the third duration of the second cyclic etch process includes multiple pulses of the first bias voltage and the fourth duration of the cyclic etch process is free of the first bias voltage, and a third ratio of t3/(t3+t4) is greater than 99%.

Another aspect of the present disclosure pertains to a semiconductor structure. The structure includes a first epitaxial source/drain (S/D) feature over a first protruding portion of a substrate, a second epitaxial S/D feature over a second protruding portion of the substrate, a third epitaxial S/D feature over a third protruding portion of the substrate, a fourth epitaxial S/D feature over a fourth protruding portion of the substrate, and an isolation structure over the substrate. The isolation structure has a base portion over a top surface of the substrate and sidewall portions over sidewalls of the first, second, third, and fourth protruding portions of the substrate. The first and second epitaxial S/D features do not merge, and the third and fourth epitaxial S/D features merge by breaking through the sidewall portions of the isolation structure.

In an embodiment, the third and fourth epitaxial S/D features merge at lower portions of the third and fourth epitaxial S/D features.

In an embodiment, the first and second epitaxial S/D features are p-type S/D features, and the third and fourth epitaxial S/D features are n-type S/D features.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor structure, comprising:
forming an active region over a substrate;
forming a dummy gate layer over the active region;
forming a hard mask layer over the dummy gate layer;
forming a patterned photoresist over the hard mask layer; and
performing an etching process to the hard mask layer and the dummy gate layer using the patterned photoresist, thereby forming patterned hard mask structures and patterned dummy gate structures, wherein the patterned hard mask structures are formed with an uneven profile having a protruding portion,
wherein the protruding portion of each of the patterned hard mask structures has a first width, wherein each of the patterned dummy gate structures has a second width, and the first width is greater than the second width.

2. The method of claim 1, wherein the dummy gate layer includes polysilicon or amorphous silicon, and the hard mask layer includes silicon oxide and silicon nitride.

3. The method of claim 1, wherein the hard mask layer includes a silicon oxide layer formed over a silicon nitride layer, and the protruding portion is the silicon nitride layer.

4. The method of claim 1, wherein the etching process is a multi-step etching process, the multi-step etching process includes one or more main plasma etching steps, one or more plasma treating steps, and one or more plasma trimming steps,
wherein the main plasma etching steps and the plasma trimming steps include applying halogen-containing gases such as Cl₂, Br₂, HBr, HCl, or combinations thereof,
wherein the plasma treating steps include O₂ ashing, CO₂ ashing, nitrogen plasma treatment, or combinations thereof.

5. The method of claim 4,
wherein one of the plasma trimming steps is a cyclic etch process, each cycle of the cyclic etch process having multiple pulses of a bias voltage and multiple pulses of a halogen-containing gas flow.

6. The method of claim 5,
wherein each cycle of the cyclic etch process includes a first duration t1 and a second duration t2 following the first duration, and
the first duration of the cyclic etch process includes multiple pulses of the bias voltage
and the second duration of the cyclic etch process is free of the bias voltage,
wherein the first duration t1 is 85-95% of a total duration of the cyclic etch process and the second duration t2 is 5-15% of the total duration of the cyclic etch process.

7. The method of claim 5, wherein the one of the plasma trimming step forms the protruding portion of each of the patterned hard mask structures.

8. The method of claim 1, further comprising:
forming gate spacers along sidewalls of the patterned dummy gate structures;
forming source/drain (S/D) trenches between the patterned dummy gate structures and in S/D regions of the active region; and
forming S/D epitaxial features in the S/D trenches.

9. The method of claim 8, wherein the active region is a first active region and the S/D epitaxial features are first S/D epitaxial features, further comprising:
forming a second active region over the substrate and adjacent to the first active region;
forming second S/D trenches between the patterned dummy gate structures and in second S/D regions of the second active region; and
forming second S/D epitaxial features in the second S/D trenches,
wherein the first S/D epitaxial features do not merge with the second S/D epitaxial features.

10. The method of claim 8, wherein the forming of the S/D trenches includes etching through the S/D regions of the active region and partially etching an isolation structure that surrounds a protruding portion of the substrate, wherein after the forming of the S/D trenches, the isolation structure still has a portion that completely surround the protruding portion of the substrate.

11. A method of forming a semiconductor structure, comprising:
depositing a dummy gate layer over an active region of a semiconductor substrate;
depositing a hard mask layer over the dummy gate layer, the hard mask layer including a first dielectric film and a second dielectric film over the first dielectric film;
performing a patterning process to the hard mask layer and the dummy gate layer, wherein the patterning process includes a first etching process having multiple etching steps and one of the etching steps is a cyclic etch process designed to form patterned stacks of the hard mask layer and the dummy gate layer with an uneven profile such that the first dielectric film of each of the patterned stacks spans a first width w1, and the dummy gate layer of each of the patterned stacks span a second width w2 less than the first width; and
recessing source/drain regions of the active region by a second etching process impacted by the uneven profile of the patterned stacks.

12. The method of claim 11, wherein
the cyclic etch process includes applying a bias voltage and a gas flow of an etch chemical,
each cycle of the cyclic etch process includes a first duration t1 and a second duration t2 following the first duration, and
the first duration of the cyclic etch process includes multiple pulses of the bias voltage and the second duration of the cyclic etch process is free of the bias voltage.

13. The method of claim 12, wherein
a first ratio of t1/(t1+t2) is less than 90%, and
a second ratio of w1/w2 is greater than 1.1.

14. The method of claim 13, wherein the first duration of the cyclic etch process includes multiple pulses of the gas flow and the second duration of the cyclic etch process is free of the gas flow.

15. The method of claim 14, wherein the multiple pulses of the bias voltage and the multiple pulses of the gas flow are synchronized.

16. The method of claim 15, wherein the multiple pulses of the bias voltage are evenly distributed in the first duration.

17. The method of claim 13,
wherein the one of the etching steps is a second etch step, the cyclic etch process is a second cyclic etch process, the bias voltage is a second bias voltage, the gas flow is a second gas flow,
wherein the first etching process further includes a first etch step, and the first etch step is a first cyclic etch process performed before the second etch step,
the first cyclic etch process includes applying a first bias voltage and a first gas flow of the etch chemical,
each cycle of the first cyclic etch process includes a third duration t3 and a fourth duration t4 following the third duration,
the third duration of the second cyclic etch process includes multiple pulses of the first bias voltage and the fourth duration of the cyclic etch process is free of the first bias voltage, and
a third ratio of t3/(t3+t4) is greater than 99%.

18. A semiconductor structure, comprising:
a first epitaxial source/drain (S/D) feature over a first protruding portion of a substrate;
a second epitaxial S/D feature over a second protruding portion of the substrate;
a third epitaxial S/D feature over a third protruding portion of the substrate;
a fourth epitaxial S/D feature over a fourth protruding portion of the substrate; and
an isolation structure over the substrate, the isolation structure having a base portion over a top surface of the substrate and sidewall portions over sidewalls of the first, second, third, and fourth protruding portions of the substrate,
wherein the first and second epitaxial S/D features do not merge,
wherein the third and fourth epitaxial S/D features merge by breaking through the sidewall portions of the isolation structure.

19. The semiconductor structure of claim 18, wherein the third and fourth epitaxial S/D features merge at lower portions of the third and fourth epitaxial S/D features.

20. The semiconductor structure of claim 18, wherein the first and second epitaxial S/D features are p-type S/D features, and the third and fourth epitaxial S/D features are n-type S/D features.
